(19) United States
(12) Patent Application Publication
(10) Pub. No.: US 2012/0326118 A1
(43) Pub. Date: Dec. 27, 2012

(54) SEMICONDUCTOR LIGHT EMITTING DEVICE AND METHOD FOR MANUFACTURING THE SAME

(75) Inventor: Koichi Nitta, Kanagawa-ken (JP)

(73) Assignee: Kabushiki Kaisha Toshiba, Tokyo (JP)

(21) Appl. No.: 13/399,549

(22) Filed: Feb. 17, 2012

(30) Foreign Application Priority Data
Jun. 24, 2011 (JP) P2011-140244

(51) Int. Cl. H01L 33/06; H01L 33/60

(52) U.S. Cl. 257/13; 438/28; 257/E33.008; 257/E33.056; 257/E33.072

(57) ABSTRACT

In one embodiment, a semiconductor light emitting device includes a substrate, an electrically-conductive reflection film, an active region, a first electrode, a transparent conductive film and a second electrode. In the active region, a first transparent electrode, a first conductivity type contact layer, a light emitting layer, a second conductivity type contact layer and a second transparent electrode are formed and stacked on the electrically-conductive reflection film. The first electrode is provided away from the active region on the electrically-conductive reflection film. One end of the transparent conductive film is provided to cover the upper portion of the second transparent electrode, while the other end of the transparent conductive film is provided above the electrically-conductive reflection film through an insulating film. The transparent conductive film is in contact with a lateral surface of the active region through the insulating film.

### CROSS REFERENCE TO RELATED APPLICATION

This application is based upon and claims the benefit of priority from the prior Japanese Patent Application No. 2011-140244, filed on Jun. 24, 2011, the entire contents of which are incorporated herein by reference.

### FIELD

Embodiments described herein relate to a semiconductor light emitting device and a method for manufacturing the same.

### BACKGROUND

A sapphire substrate having insulating properties, a GaN (gallium nitride) substrate having electrical conductivity, and the like are used for nitride-based semiconductor light emitting devices. In a case where the sapphire substrate is applied to the nitride-based semiconductor light emitting device, an anode electrode joined to a first bonding wire connected to a first external terminal and a cathode electrode joined to a second bonding wire connected to a second external terminal are formed flush with each other.

This causes a problem that the anode electrode reflecting light produced in the inside lowers the light extraction efficiency. Another problem is that because the anode electrode and the cathode electrode are formed on the non-active region of the nitride-based semiconductor light emitting device, a reduction in the chip size cannot be achieved in the nitride-based semiconductor light emitting device which is relatively expensive.

The application of the GaN (gallium nitride) substrate having the electrical conductivity to the nitride-based semiconductor light emitting device causes a problem that the expensive GaN (gallium nitride) substrate makes it difficult to reduce costs of chips of the nitride-based semiconductor light emitting device.

### BRIEF DESCRIPTION OF THE DRAWINGS

FIG. 1 is a schematic plan view showing a semiconductor light emitting device of a first embodiment;

FIG. 2 is a schematic cross-sectional view of the semiconductor light emitting device taken along the A-A line of FIG. 1;

FIG. 3 is a cross-sectional view showing one of the steps for manufacturing the semiconductor light emitting device of the first embodiment;

FIG. 4 is a cross-sectional view showing one of the steps for manufacturing the semiconductor light emitting device of the first embodiment;

FIG. 5 is a cross-sectional view showing one of the steps for manufacturing the semiconductor light emitting device of the first embodiment;

FIG. 6 is a cross-sectional view showing one of the steps for manufacturing the semiconductor light emitting device of the first embodiment;

FIG. 7 is a cross-sectional view showing one of the steps for manufacturing the semiconductor light emitting device of the first embodiment;

FIG. 8 is a cross-sectional view showing one of the steps for manufacturing the semiconductor light emitting device of the first embodiment;

FIG. 9 is a cross-sectional view showing one of the steps for manufacturing the semiconductor light emitting device of the first embodiment;

FIG. 10 is a cross-sectional view showing one of the steps for manufacturing the semiconductor light emitting device of the first embodiment;

FIG. 11 is a schematic cross-sectional view showing a semiconductor light emitting device of a modification;

FIG. 12 is a schematic cross-sectional view showing the semiconductor light emitting device of the modification;

FIG. 13 is a schematic plan view showing a semiconductor light emitting device of a second embodiment;

FIG. 14 is a schematic cross-sectional view of the semiconductor light emitting device taken along the B-B line of FIG. 13;

FIG. 15 is a cross-sectional view showing one of the steps for manufacturing the semiconductor light emitting device of the second embodiment;

FIG. 16 is a cross-sectional view showing one of the steps for manufacturing the semiconductor light emitting device of the second embodiment;

FIG. 17 is a schematic cross-sectional view showing a semiconductor light emitting device of a third embodiment;

FIG. 18 is a cross-sectional view showing one of the steps for manufacturing the semiconductor light emitting device of the third embodiment; and

FIG. 19 is a cross-sectional view showing one of the steps for manufacturing the semiconductor light emitting device of the third embodiment.

### DETAILED DESCRIPTION

In one embodiment, a semiconductor light emitting device includes a substrate, an electrically-conductive reflection film, an active region, a first electrode, a transparent conductive film and a second electrode. The electrically-conductive reflection film is provided on the substrate. In the active region, a first transparent electrode, a first conductivity type contact layer, a light emitting layer, a second conductivity type contact layer and a second transparent electrode are formed and stacked on the electrically-conductive reflection film. The first electrode is provided away from the active region on the electrically-conductive reflection film. One end of the transparent conductive film is provided to cover the upper portion of the second transparent electrode, while the other end of the transparent conductive film is provided above the electrically-conductive reflection film through an insulating film. The transparent conductive film is in contact with a lateral surface of the active region through the insulating film. The second electrode is provided on the other end of the transparent conductive film.

In another embodiment, a method for manufacturing a semiconductor light emitting device includes first to 10th steps. In the first step, an n-type contact layer, a MQW light emitting layer and a p-type contact layer are formed and stacked on a first substrate by epitaxial growth. In the second step, a p-side transparent electrode and an adhesive sheet are formed and stacked on the p-type contact layer. In the third step, the first substrate is detached by forming a detachment interface between the first substrate and the n-type contact layer by irradiating the first substrate with a laser beam from the back side of the first substrate to the n-type contact layer side. In the fourth step, an n-side transparent electrode is formed on the n-type contact layer. In the fifth step, an active region, in which the n-side transparent electrode, the n-type contact layer, the MQW light emitting layer, the p-type contact layer and the p-side transparent electrode are stacked, is divided into chips. In the 6th step, an electrically-conductive reflection film is formed on a second substrate. In the 7th step, a chip having the active region is placed on the electrically-conductive reflection film, and is bonded to the electrically-conductive reflection film and the second substrate. In the 8th step, an insulating film is formed on the electrically-conductive reflection film and on a lateral surface of the chip of the active region. In the 9th step, a transparent conductive film is formed to cover the upper portion of the p-side transparent electrode as well as the lateral surface and upper portion of the insulating film, and to be isolated from the n-side transparent electrode, the n-type contact layer, the MQW light emitting layer and the p-type contact layer by the insulating film. In the 10th step, a cathode electrode is formed on an exposed portion of the electrically-conductive reflection film, and an anode electrode is formed on the transparent conductive film in a region where the second substrate, the electrically-conductive reflection film, the insulating film and the transparent conductive film are formed and stacked.

Hereinafter, further plural examples are described with reference to the drawings. In the drawings, the same numeral indicates the same or similar portions.

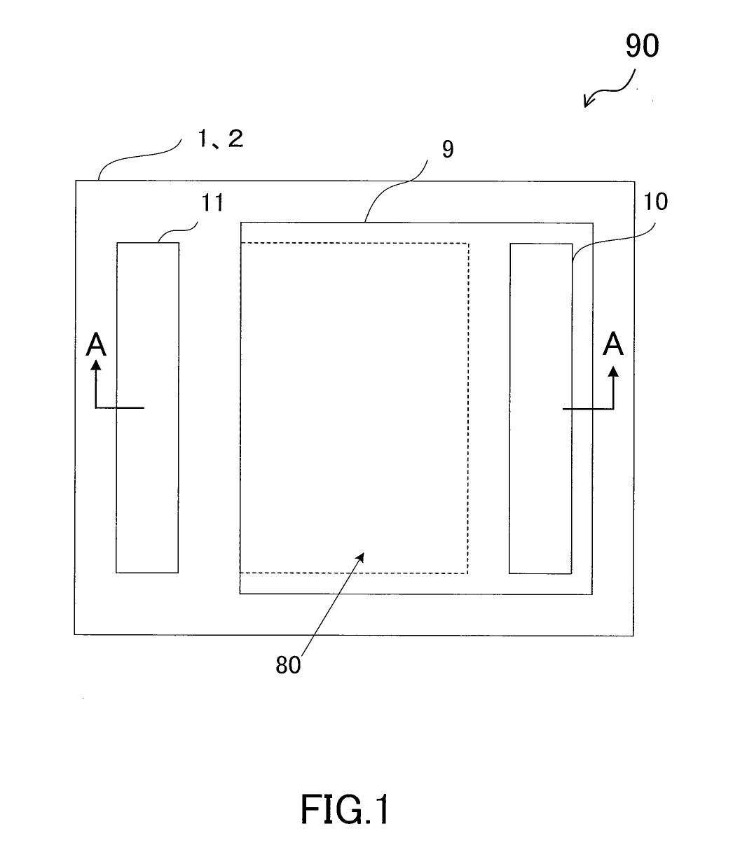

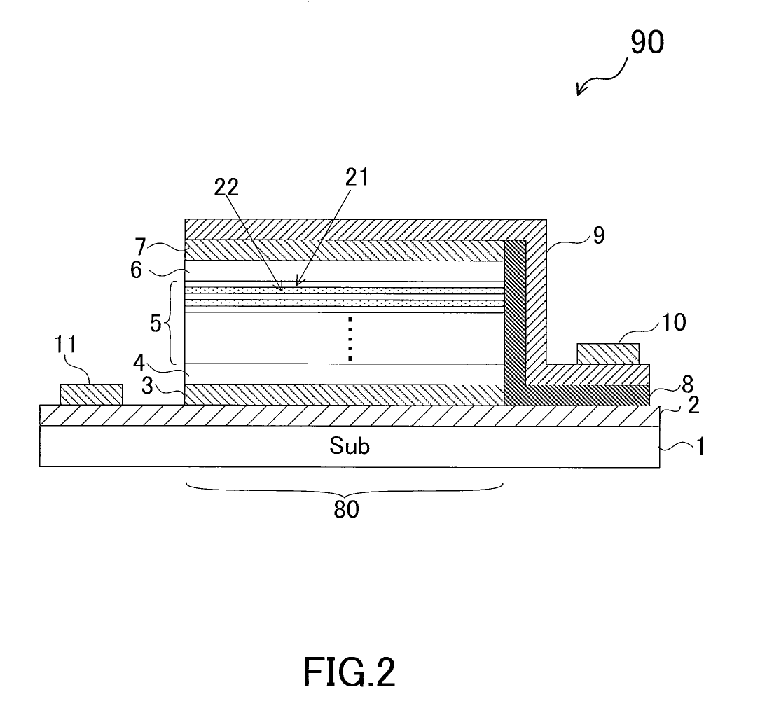

Descriptions will be provided for a semiconductor light emitting device and a method for manufacturing the same of a first embodiment with reference to FIGS. 1 and 2. FIG. 1 is a schematic plan view showing the semiconductor light emitting device. FIG. 2 is a schematic cross-sectional view of the semiconductor light emitting device taken along the A-A line of FIG. 1. The embodiment enhances the light extraction efficiency by using the following scheme. An n-side transparent electrode, an n-type contact layer, a MQW light emitting layer, a p-type contact layer and a p-side transparent electrode, which constitute an active region, are formed and stacked on an electrically-conductive reflection film. A transparent conductive film is formed to cover the upper surface of the p-side transparent electrode. An anode electrode is provided away from the active region on the transparent conductive film provided above the electrically-conductive reflection film through an insulating film.

Here, the n-side transparent electrode is a transparent electrode that is electrically connected to an anode electrode. The p-side transparent electrode is a transparent electrode that is electrically connected to a cathode electrode.

As shown in FIG. 1, in a semiconductor light emitting device 90, a cathode electrode 11 and an active region 80 are provided on a substrate 1/an electrically-conductive reflection film 2, while an anode electrode 10 is provided on a transparent conductive film 9. The transparent conductive film 9 is provided to the upper surface of the active region 80. The transparent conductive film 9 connects a p-type transparent electrode, which is provided to the active region 80, and the anode electrode 10 together. The anode electrode 10 is not provided to the upper surface of the active region 80.

The semiconductor light emitting device 90 is a GaN LED (light emitting diode) using a inexpensive silicon substrate as the substrate 1. When the semiconductor light emitting device 90 is sealed in an assembling process, the anode electrode 10 is connected to a first external terminal (not illustrated) through a first bonding wire (not illustrated), and the cathode electrode 11 is connected to a second external terminal (not illustrated) through a second bonding wire (not illustrated). The sealed semiconductor light emitting device 90 is used for indoor and outdoor indicator lamps, indoor and outdoor illumination, head lamps and stop lamps of automobiles, traffic signs, traffic signals, portable lamps and the like.

As shown in FIG. 2, the electrically-conductive reflection film 2 is provided on a first principal surface of the substrate 1. The electrically-conductive reflection film 2 functions to reflect light produced in the active region 80, and not to transmit the light to the substrate 1. A Ag (silver) alloy reflection film, for example, is used as the electrically-conductive reflection film 2. In the embodiment, a Ag (silver)-Pd (palladium)-Cu (copper)-Ge (germanium)-based silver alloy is used as the Ag (silver) alloy reflection film. Instead, however, a Ag (silver)-Ge (germanium)-based silver alloy, a Ag (silver)-Au (gold)-Sn (tin)-based silver alloy, or the like may be used as the Ag (silver) alloy reflection film.

The cathode electrode 11 is provided on the first principal surface of the electrically-conductive reflection film 2 (in the left end portion in FIGS. 1 and 2). The cathode electrode 11 is made of Ni (nickel)/Au (gold), for example.

The active region 80 is provided on the first principal surface of the electrically-conductive reflection film 2 (in the center portion in FIGS. 1 and 2). The active region 80 emits light when a voltage is applied to the anode electrode 10 and the cathode electrode 11. The active region 80 includes an n-side transparent electrode 3, an n-type contact layer 4, a MQW light emitting layer 5, a p-type contact layer 6 and a p-side transparent electrode 7 which are formed and stacked. MQW (multiple quantum well) means a structure including a plurality of quantum well layers and a plurality of barrier layers.

In the embodiment, an ITO (indium tin oxide) film is used as the n-side transparent electrode 3 and the p-side transparent electrode 7. The ITO film has a transmittance of 95% and a resistivity of 5×10⁴Ω/cm² or less, for example. It should be noted that a ZnO film, an AZO film (obtained by adding Al₂O₃ to ZnO), GZO film (obtained by adding Ga₂O₃ to ZnO) or the like may be used instead of the ITO film. An n-type GaN layer doped with Si is used as the n-type contact layer 4. Instead, however, an AlₓGa₁₋ₓN layer (0≦x≦0.5) may be used as the n-type contact layer 4. The MQW light emitting layer 5 is provided with an alternate series of a barrier layer 21 and a well layer 22. In this respect, the barrier layer 21 is made of an undoped GaN layer. The well layer 22 is made of an InAlGaN layer subjected to lattice matching to GaN. One well layer 22 is interposed between each two corresponding neighboring barrier layers 21. A GaN layer doped with Mg is used as the p-type contact layer 6. Instead, however, an Al_{y}Ga_{1-y}N layer ((0≦y≦0.5) may be used as the p-type contact layer 6. It should be noted that a SQW (single quantum well) light emitting layer may be used instead of the MQW light emitting layer 5.

An insulating film 8 is provided to the right end of the active region 80 and on the first principal surface of the electrically-conductive reflection film 2 (in the right end portion in FIG. 2). A SiO₂ film (a silicon dioxide film) is used as the insulating film 8. Instead, however, a SiN film (a silicon nitride film) or the like may be used as the insulating film 8. It should be noted that although not illustrated, the insulating film is provided to the left end portion of the active region 80, and the periphery of the active region 80 is covered with the insulating film.

The transparent conductive film 9 is provided to the upper surface of the p-side transparent electrode 7, as well as to the upper surface and lateral surface of the insulating film 8 in a way that the transparent conductive film 9 covers the p-side transparent electrode 7. An ITO film is used as the transparent conductive film 9. Instead, however, a ZnO film, an AZO film, a GZO film or the like may be used as the transparent conductive film 9.

The semiconductor light emitting device 90 emits light, which is produced in the MQW light emitting layer 5, through the n-side transparent electrode 3 made of the ITO film and placed on the lower side, through the p-side transparent electrode 7 made of the ITO film and placed on the upper side, as well as through the transparent conductive film 9 made of the ITO film and placed on the upper and lateral sides. In addition, the semiconductor light emitting device 90 can enhance the light extraction efficiency to a large extent, because no anode electrode is formed on the upper surface of the active region 80. Furthermore, the semiconductor light emitting device 90 can suppress a piezo-electric field which occurs due to lattice mismatch stress, and accordingly can lower the operating voltage, because the InAlGaN layer subjected to the lattice matching to GaN is used as the well layers 22 of the MQW light emitting layer 5. The contact layers and the barrier layers may be made of an InAlGaN layer whose composition is different from that of the InAlGaN layer used as the well layers, because the effects of this structure can be applied by matching the lattice constant of the well layers, which serve as the light emitting layers, with the lattice constant of the barrier layers and the lattice constant of the contact layers.

In addition, the semiconductor light emitting device 90 makes it possible to reduce the chip size of the nitride-based semiconductor light emitting device which is relatively expensive, because the anode electrode 10 and the cathode electrode 11, which are the non-active regions, are formed on the substrate 1/the electrically-conductive reflection film 2, because the inexpensive silicon substrate is used as the substrate 1, and because only the active region 80 is formed from the GaN-based semiconductor layer. Accordingly, it is possible to reduce the costs of the semiconductor light emitting device 90.

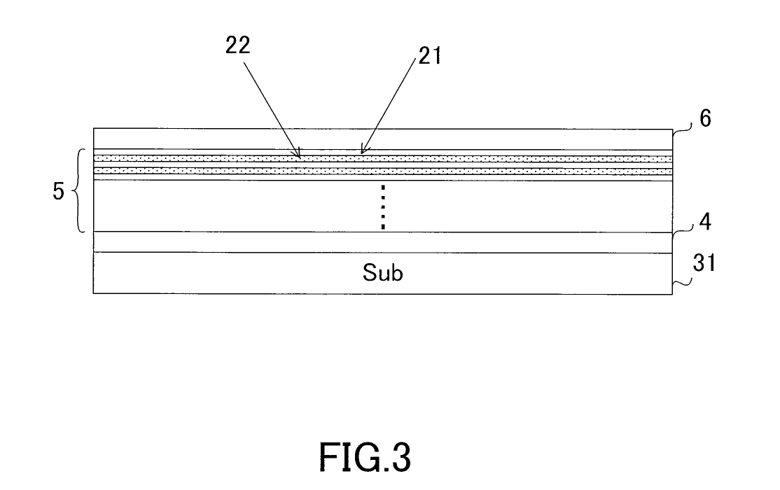

Next, descriptions will be provided for a method for manufacturing a semiconductor light emitting device with reference to FIGS. 3 to 10. FIGS. 3 to 10 are cross-sectional views showing the respective steps for manufacturing the light emitting device.

To begin with, a substrate 31 made of sapphire (Al₂O₃) is prepared as shown in FIG. 3. The n-type contact layer 4, the MQW light emitting layer 5 and the p-type contact layer 6, which are epitaxial layers whose compositions are different from one another, are consecutively formed and stacked on the first principal surface of the substrate 31 by MOCVD (metal organic chemical vapor deposition) which is an epitaxial growth method. Incidentally, MBE (molecular beam epitaxy) may be used instead of MOCVD.

The growth temperature of the n-type contact layer 4 is set in a range from 1000° C. to 1200° C., for example. The film thickness of the n-type contact layer 4 is set in a range from 3 μm to 12 μm. With regard to the MQW light emitting layer 5, the growth temperature of the barrier layers 21 is set in a range from 800° C. to 1100° C., for example, while the growth temperature of the well layers 22 is set in a range from 700° C. to 900° C., for example. The growth temperature of the p-type contact layer 6 is set in a range from 1000° C. to 1200° C., for example. The film thickness of the p-type contact layer 6 is set in a range from 0.4 μm to 2 μm.

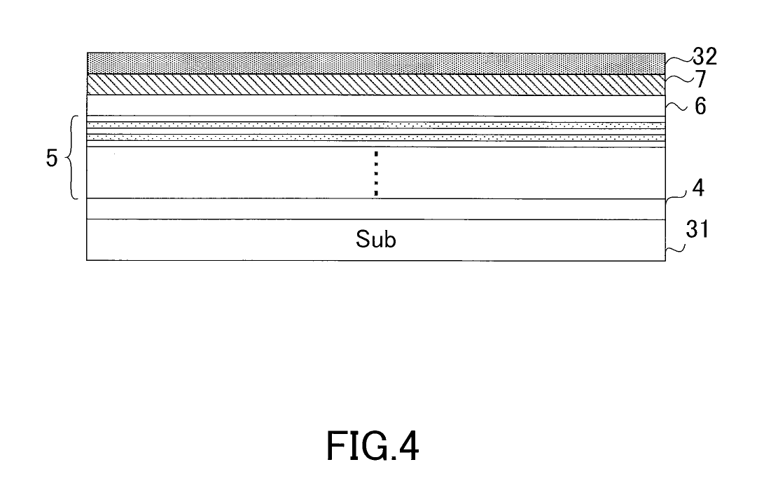

Next, as shown in FIG. 4, the p-side transparent electrode 7 made of the ITO film is formed on the first principal surface of the p-type contact layer 6 by sputtering, for example. The ITO film is made of In₂O₃ (indium oxide) containing 10 wt % of SnO₂ (tin oxide), for example. Incidentally, the p-side transparent electrode 7 may be formed by evaporation, instead of by sputtering. After the p-side transparent electrode 7 is formed, an adhesive sheet 32 made of an organic film is attached to the first principal surface of the p-side transparent electrode 7.

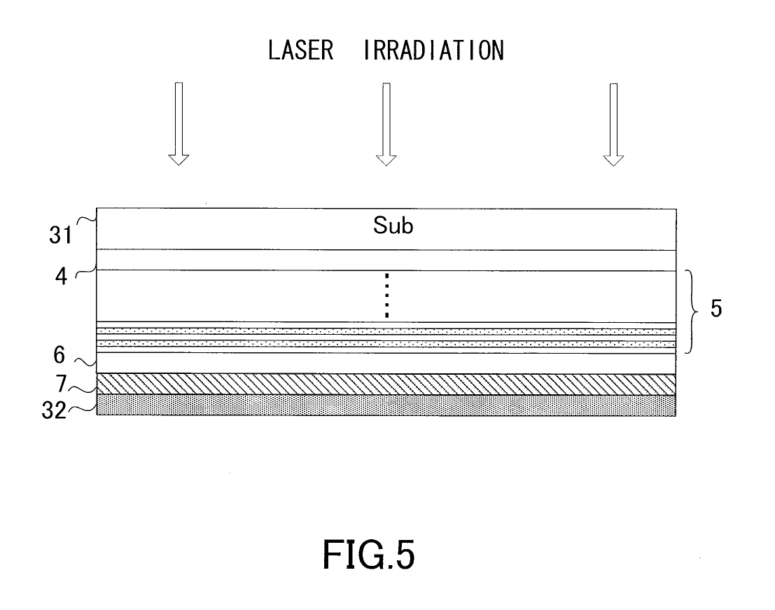

Subsequently, as shown in FIG. 5, the substrate 31 is irradiated with a laser beam from the second principal surface (back surface) side opposed to the first principal surface side of the substrate 31. The laser beam is applied to laser liftoff for detaching the substrate 31 from the active region 80 inclusive of the n-type contact layer 4. A titanium-sapphire laser beam, for example, is used as the laser beam. Conditions employed for the laser beam include an 800-nanometer wavelength and a 100-femtosecond pulse width.

Because the substrate 31 made of sapphire (Al₂O₃) transmits the laser beam, a portion of the n-type contact layer 4 made of GaN, which is closer to the interface of the substrate 31, is decomposed into metallic Ga (gallium) and N₂ (nitrogen) by the laser beam. A portion of the substrate 31 made of sapphire (Al₂O₃), which is closer to the interface with the n-type contact layer 4, is melted by heat which is produced in conjunction with the decomposition as well. As a result, in the portion of the substrate 31 made of sapphire (Al₂O₃), an altered region is generated, and a detachment interface is formed.

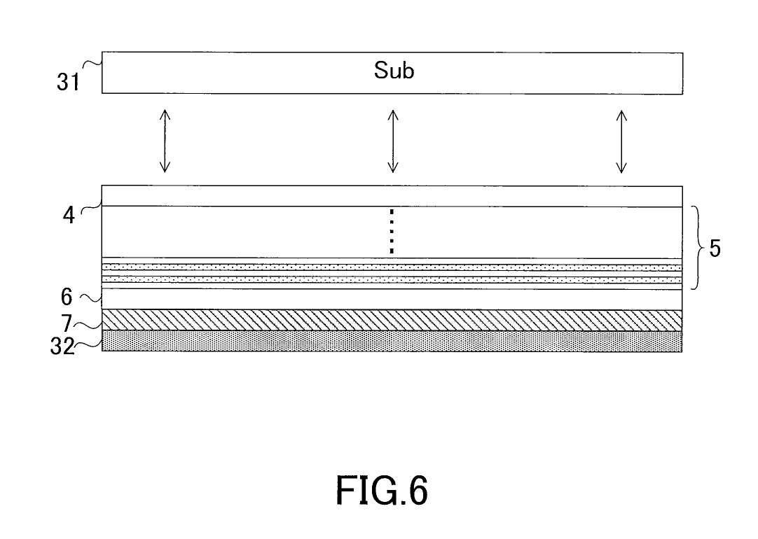

Thereafter, as shown in FIG. 6, the substrate 31 is detached from the active region 80 inclusive of the n-type contact layer 4 along the detachment interface by heating and cooling, for example. In this respect, the substrate 31 is detached by laser liftoff. Instead, however, the substrate 31 may be removed by etching.

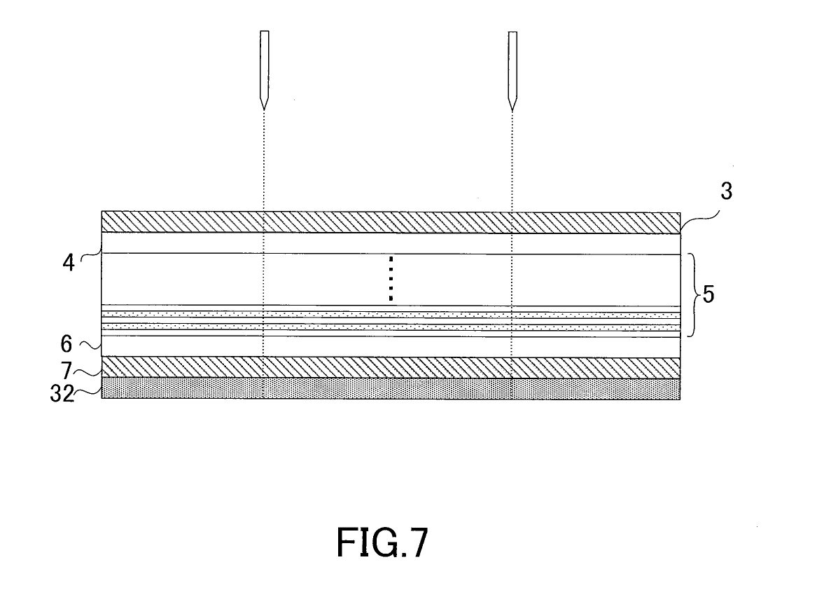

Next, as shown in FIG. 7, the n-side transparent electrode 3 made of the ITO film is formed on the first principal surface of the n-type contact layer 4 by sputtering. The ITO film is made of In₂O₃ (indium oxide) containing 10 wt % of SnO₂ (tin oxide), for example. It should be noted that the n-side transparent electrode 3 may be formed by evaporation, instead of by sputtering. After the n-side transparent electrode 3 is formed, the active region 80 is subjected to a scribing and breaking process, or to a blade dicing process, from the n-side transparent electrode 3. Then, the resultant active region 80 is divided into pieces by stretching the adhesive sheet 32. Thereby, the active region 80 is divided into chips by detaching the adhesive sheet 32 from the active region 80.

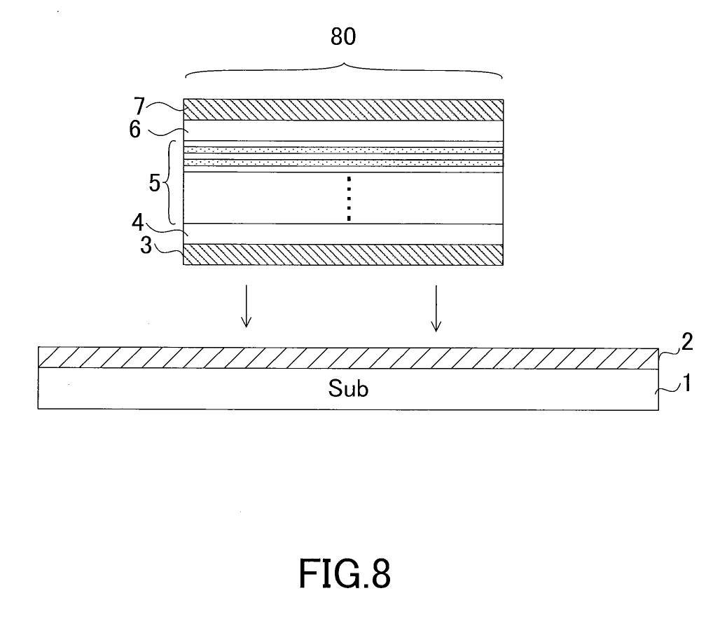

Subsequently, as shown in FIG. 8, the electrically-conductive reflection film 2 made of the Ag (silver) alloy is formed on the first principal surface of the substrate 1 made of silicon by sputtering, for example. A chip having the active region 80 is placed on and bonded to the first principal surface of the substrate 1 on which the electrically-conductive reflection film 2 is formed.

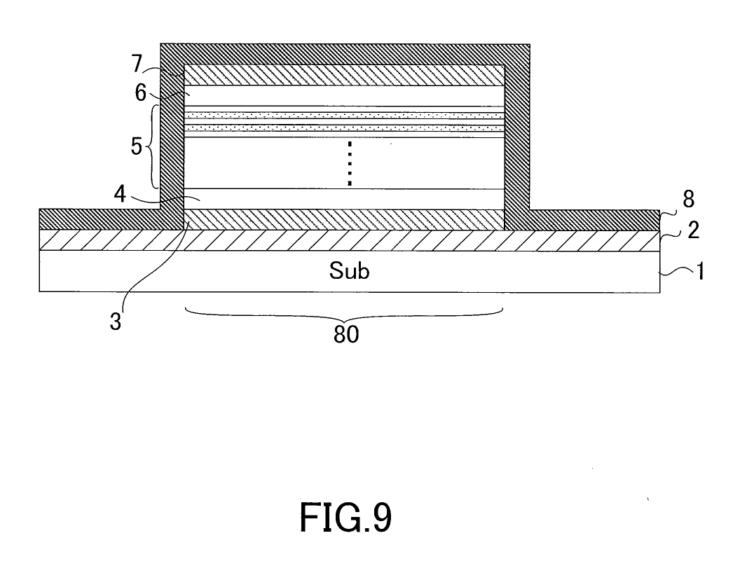

Thereafter, as shown in FIG. 9, the insulating film 8 made of the SiO₂ film (silicon dioxide film) is formed on the upper surface and lateral surface of the active region 80, and on the electrically-conductive reflection film 2, by CVD (chemical vapor deposition), for example.

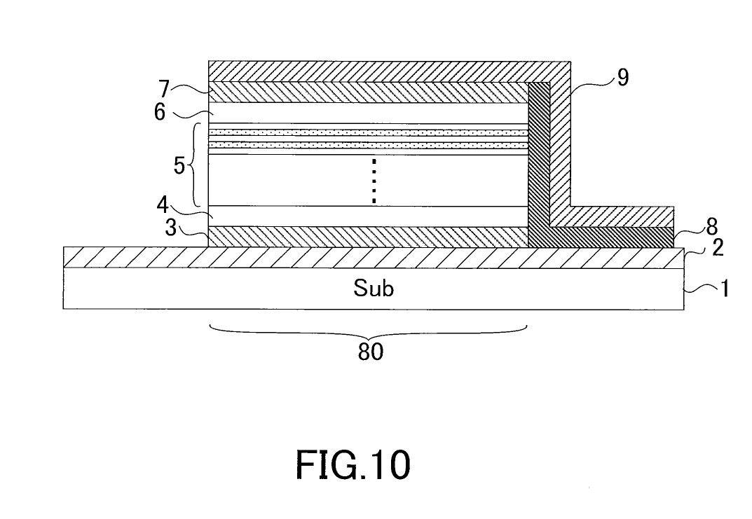

Next, as shown in FIG. 10, the insulating film 8 is etched by using a first resist film (not illustrated) as a mask. After the first resist film is removed, the transparent conductive film 9 made of the ITO film is formed on the upper surface and lateral surface of the active region 80, and on the upper surface and lateral surface of the insulating film 8, as well as on the electrically-conductive reflection film 2, by sputtering. The ITO film is made of In₂O₃ (indium oxide) containing 10 wt % of SnO₂ (tin oxide), for example. It should be noted that the transparent conductive film 9 may be formed by evaporation, instead of by sputtering. After the transparent conductive film 9 is formed, the transparent conductive film 9 is etched by using a second resist film (not illustrated) as a mask. After the second resist film is removed, the anode electrode 10, the cathode electrode 11 and the like are formed by use of a well-known technique. Thereby, the semiconductor light emitting device 90 is completed.

As described above, in the semiconductor light emitting device and the method for manufacturing the same of the embodiment, the cathode electrode 11 and the active region 80 are provided on the substrate 1/the electrically-conductive reflection film 2, and the anode electrode 10 is provided on the transparent conductive film 9. The transparent conductive film 9 is provided on the upper surface of the active region 80. The transparent conductive film 9 connects the p-type transparent electrode, which is provided to the active region 80, and the anode electrode 10 together. The active region 80 includes the n-side transparent electrode 3, the n-type contact layer 4, the MQW light emitting layer 5, the p-type contact layer 6 and the p-side transparent electrode 7 which are formed stacked. The light produced in the MQW light emitting layer 5 is emitted through the n-side transparent electrode 3 made of the ITO film and placed on the lower side, and through the p-side transparent electrode 7 made of the ITO film and placed on the upper side, and through the transparent conductive film 9 made of the ITO film and placed on the upper and lateral sides. The n-type contact layer 4, the MQW light emitting layer 5 and the p-type contact layer 6 are formed and stacked on the substrate 31 by MOCVD. The substrate 31 is detached by laser liftoff.

Accordingly because no anode electrode is formed on the upper surface of the active region 80, the light extraction efficiency can be enhanced to a large extent. Moreover, it is possible to reduce the chip size of the active region 80 which operates as the light emitting element, and to decrease the costs of the semiconductor light emitting device 90 to a large extent, because the anode electrode 10 and the cathode electrode 11, which are the non-active regions, are formed on the substrate 1/the electrically-conductive reflection film 2, because the inexpensive silicon substrate is used as the substrate 1, and because only the active region 80 is made of the GaN-based semiconductor layer.

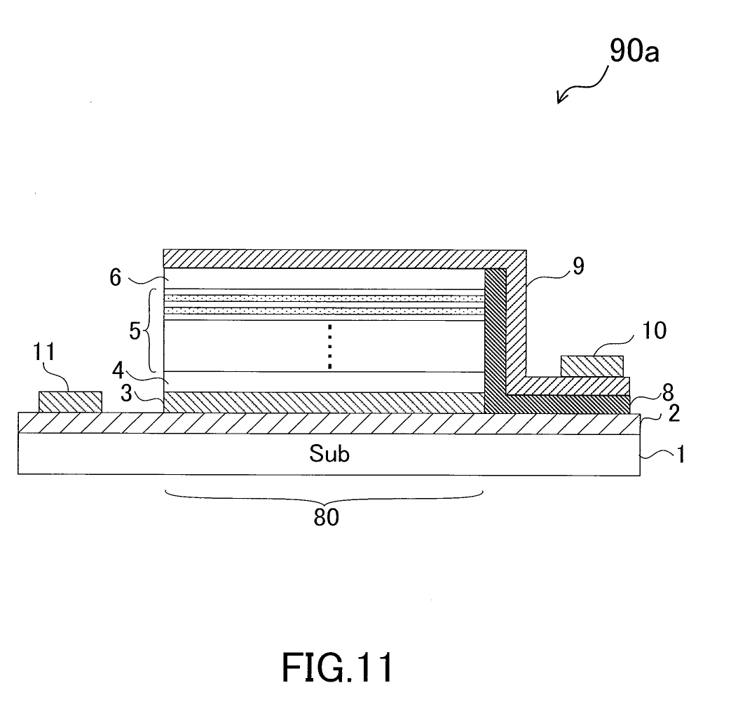

It should be noted that although the p-side transparent electrode 7 and the transparent conductive film 9 are formed and stacked on the p-type contact layer 6 in the embodiment, the invention is not limited to the above case. As in a semiconductor light emitting device 90a of a modification shown in FIG. 11, the transparent conductive film 9 may be formed directly on the p-type contact layer 6 with the p-side transparent electrode 7 omitted. Furthermore, when a Si substrate is used as the substrate for the crystal growth, the substrate can be enlarged in diameter, and the costs can be further reduced. When far-infrared radiation is used to detach the substrate, the substrate can be irradiated with the laser beam from the Si substrate side of the substrate.

Moreover, when a silicon substrate is used, it is possible to etch the silicon substrate by using an etching solution, and to reduce the production costs.

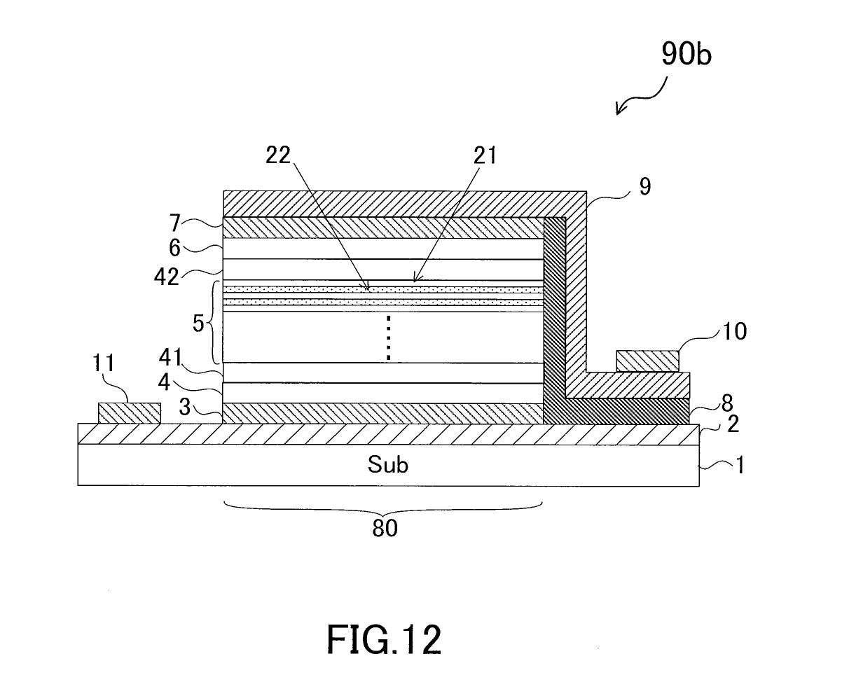

Otherwise, as in a semiconductor light emitting device 90b of another modification shown in FIG. 12, a configuration may be used in which an n-type clad layer 41 is provided between the n-type contact layer 4 and the MQW light emitting layer 5 while a p-type clad layer 42 is provided between the MQW light emitting layer 5 and the p-type contact layer 6.

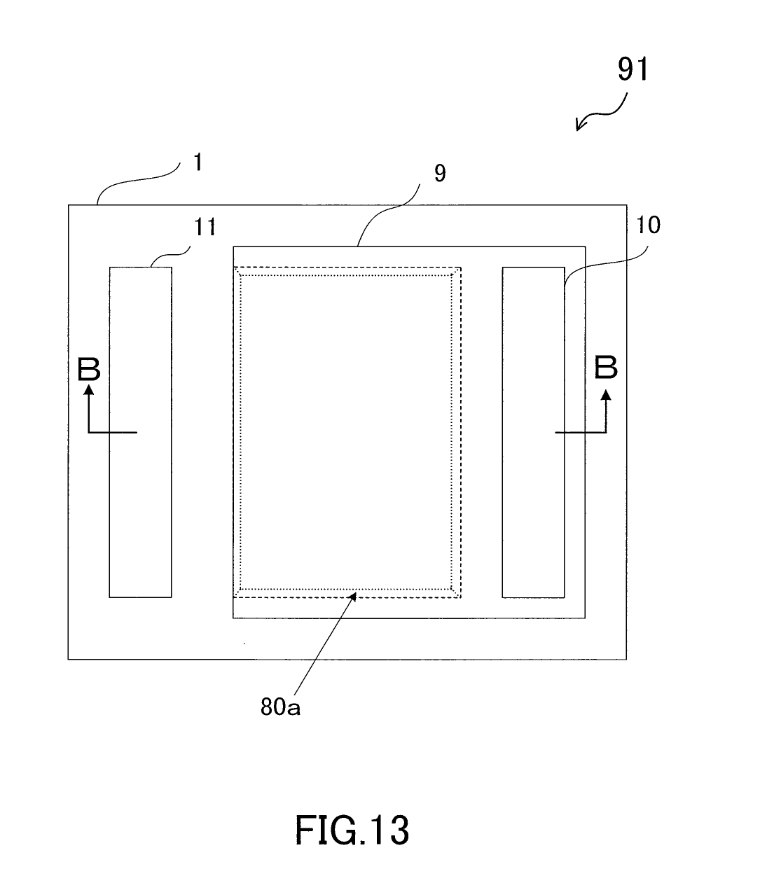

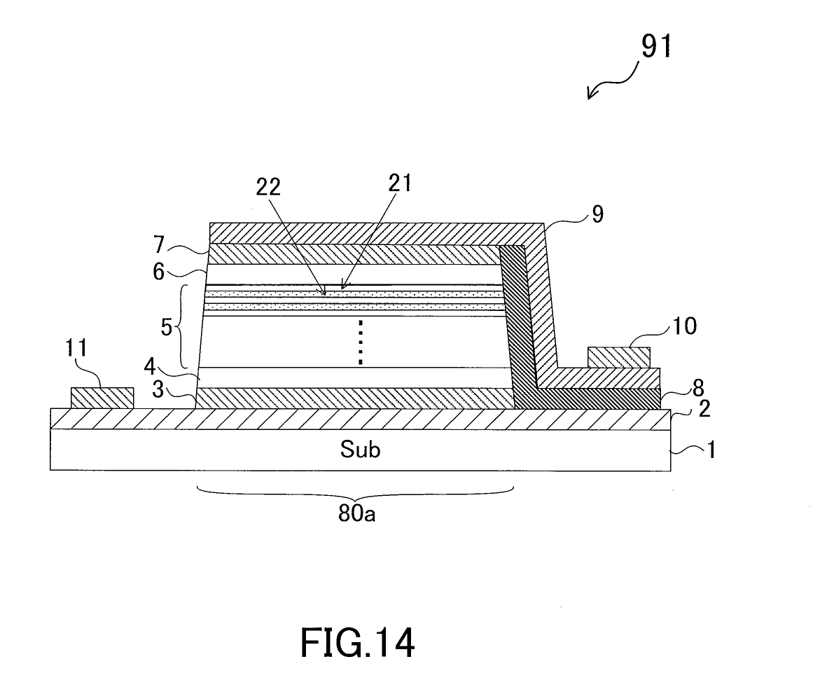

Descriptions will be provided for a semiconductor light emitting device and a method for a manufacturing the same of a second embodiment with reference to FIGS. 13 and 14. FIG. 13 is a schematic plan view showing the semiconductor light emitting device. FIG. 14 is a schematic cross-sectional view showing the semiconductor light emitting device taken along the B-B line of FIG. 13. In the embodiment, the active region is formed to have a cross section of a trapezoidal shape whose lower side is longer than the upper side, and the gradient of the lateral sides of the active region is accordingly made gentle, as well as thereby, the step coverage of the transparent conductive film is enhanced.

Hereinafter, a portion with the same configuration in the first embodiment is provided with the same numeral, a description of the portion will not be repeated, and only a portion with a different configuration is described.

As shown in FIG. 13, in a semiconductor light emitting device 91, the cathode electrode 11 and an active region 80a are provided on the substrate 1/the electrically-conductive reflection film 2, while the anode electrode 10 is provided on the transparent conductive film 9. The transparent conductive film 9 is provided to the upper surface of the active region 80a. The transparent conductive film 9 connects the p-side transparent electrode, which is provided to the active region 80a, and the anode electrode 10 together. The anode electrode 10 is not provided to the upper surface of the active region 80a.

The semiconductor light emitting device 91 is a GaN LED using a inexpensive silicon substrate as the substrate 1. When the semiconductor light emitting device 91 is sealed in an assembling process, the anode electrode 10 is connected to a first external terminal (not illustrated) through a first bonding wire (not illustrated), and the cathode electrode 11 is connected to a second external terminal (not illustrated) through a second bonding wire (not illustrated). The sealed semiconductor light emitting device 91 is used for indoor and outdoor indicator lamps, indoor and outdoor illumination, head lamps and stop lamps of automobiles, traffic signs, traffic signals, portable lamps and the like.

As shown in FIG. 14, the electrically-conductive reflection film 2 functions to reflect light produced in the active region 80a, and not to transmit the light to the substrate 1. The active region 80a is provided on the first principal surface of the electrically-conductive reflection film 2 (in the center portion in FIG. 14). The active region 80a has a cross-sectional shape which is wider in the bottom surface than in the upper surface. Although the active region 80a is different in shape from the active region 80 of the first embodiment, the active region 80a has the same structure as does the active region 80 of the first embodiment.

In the semiconductor light emitting device 91, the two end portions of the active region 80a have a normally taper shape, but not a vertical shape. For this reason, it is possible to equalize the film thickness of the transparent conductive film 9 which is provided on the p-side transparent electrode 7, to the lateral surface of the active region 80a, and on the insulating film 8. Accordingly, the resistivity and the transmittance can be made stable. Even in the case where the transparent conductive film 9 is formed by sputtering which tends to make the coverage of the transparent conductive film 9 insufficient, the step coverage does not become worse.

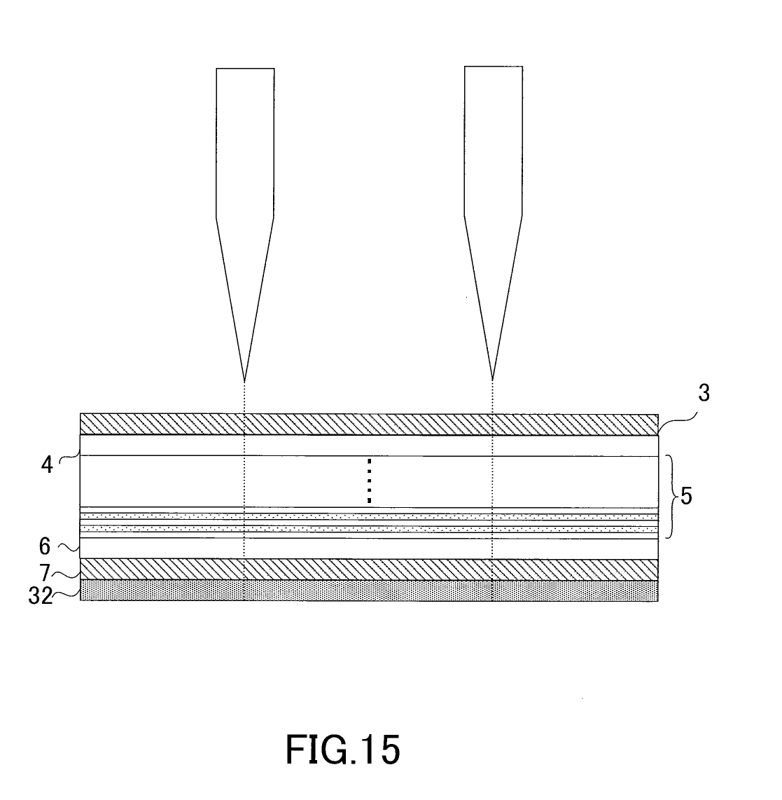

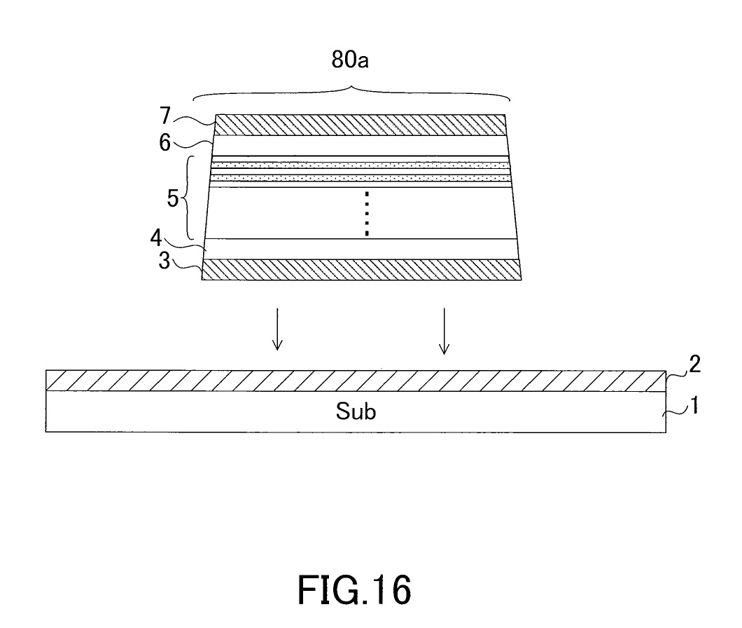

Next, descriptions will be provided for a method for manufacturing a semiconductor light emitting device with reference to FIGS. 15 to 16. FIGS. 15 to 16 are cross-sectional views showing the respective steps for manufacturing the light emitting device.

As shown in FIG. 15, after the n-side transparent electrode 3 is formed, the active region 80 is divided into chips by applying blades each having a sharp edge with a wider body to the active region 80 from above the n-side transparent electrode 3.

Next, as shown in FIG. 16, a chip having the active region 80a, which has the cross-sectional shape wider in the bottom surface than in the upper surface, is placed on and bonded to the first principal surface of the substrate 1 on which the electrically-conductive reflection film 2 is formed. Because the ensuing steps are the same as those of the first embodiment, descriptions for such steps will be omitted.

As described above, in the semiconductor light emitting device and the method for manufacturing the same of the embodiment, the cathode electrode 11 and the active region 80a are provided on the substrate 1/the electrically-conductive reflection film 2, and the anode electrode 10 is provided on the transparent conductive film 9. The transparent conductive film 9 is provided on the upper surface of the active region 80a. The transparent conductive film 9 connects the p-type transparent electrode, which is provided to the active region 80a, and the anode electrode 10 together. The active region 80a includes the n-side transparent electrode 3, the n-type contact layer 4, the MQW light emitting layer 5, the p-type contact layer 6 and the p-side transparent electrode 7 which are formed and stacked. The active region 80a has a cross-sectional shape which is wider in the bottom surface than in the upper surface.

Accordingly, the embodiment can bring about the same effects as does the first embodiment, and additionally can makes it possible to equalize the film thickness of the transparent conductive film 9, and to stabilize the resistivity and the transmittance.

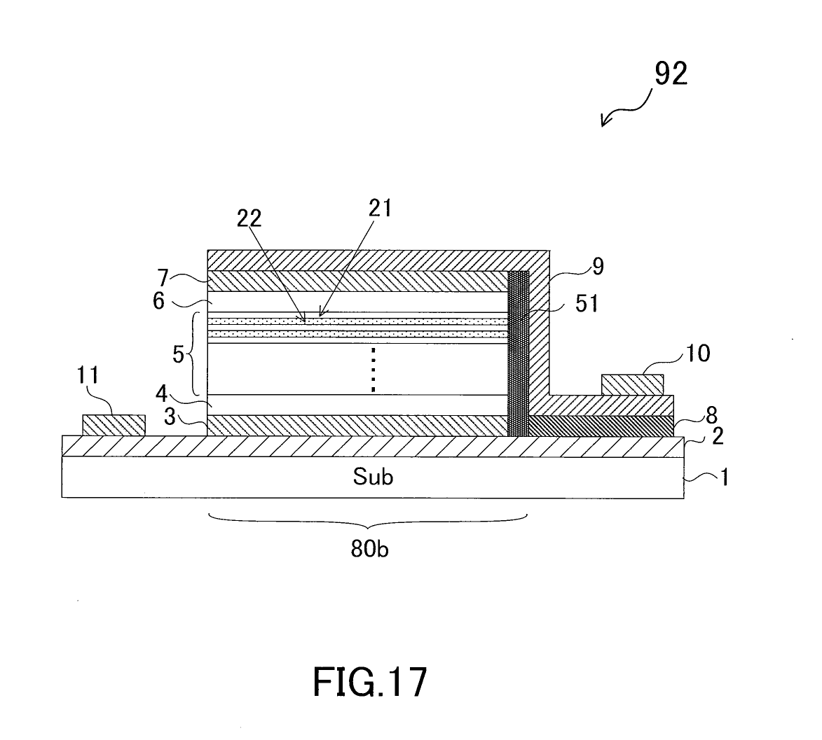

Descriptions will be provided for a semiconductor light emitting device and a method for manufacturing the same of a third embodiment with reference to FIG. 17. FIG. 17 is a schematic cross-sectional view showing the semiconductor light emitting device. In the embodiment, an isolation region is provided to the active region, and the isolation region separates the lateral surface of the active region from the transparent electrode film.

Hereinafter, a portion with the same configuration in the first embodiment is provided with the same numeral, a description of the portion will not be repeated, and only a portion with a different configuration is described.

As shown in FIG. 17, in a semiconductor light emitting device 92, an active region 80b is provided on the first principal surface of the electrically-conductive reflection film 2 (in the center portion in FIG. 17). The active region 80b emits light when a voltage is applied to the anode electrode 10 and the cathode electrode 11. The active region 80b includes the n-side transparent electrode 3, the n-type contact layer 4, the MQW light emitting layer 5, the p-type contact layer 6 and the p-side transparent electrode 7 which are formed and stacked. An isolation region 51 is provided to the right end of the active region 80b in FIG. 17. The isolation region 51 electrically insulates and isolates the n-side transparent electrode 3, the n-type contact layer 4, the MQW light emitting layer 5, and the p-type contact layer 6 from the transparent conductive film 9. In this respect, trench isolation for embedding an insulator in a groove 52 is used for the isolation region 51. Instead, however, implantation isolation or the like may be used for the isolation region 51.

As shown in FIG. 17, the left end portion of the insulating film 8 provided on the substrate 1/the electrically-conductive reflection film 2 is in contact with the isolation region 51.

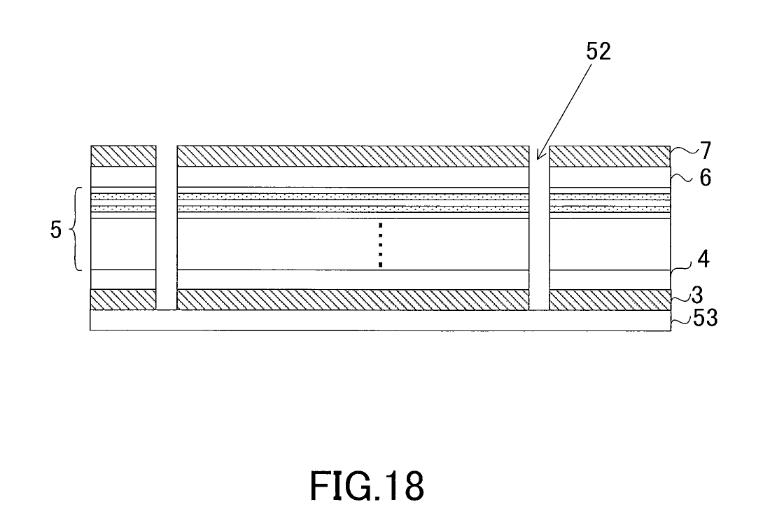

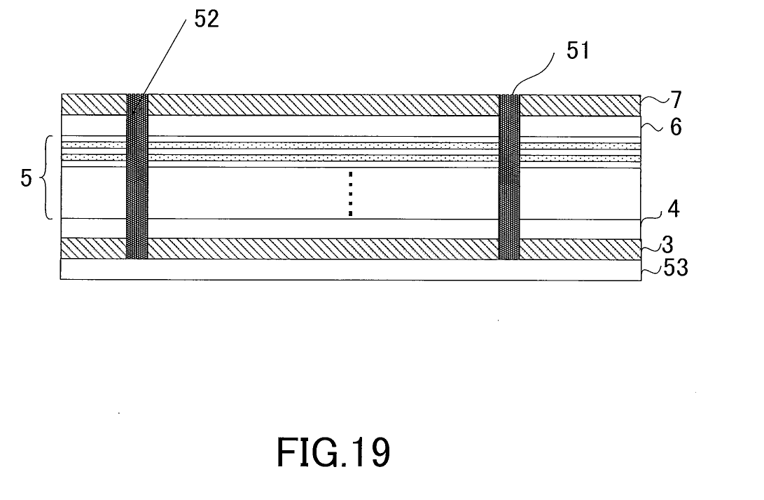

Next, descriptions will be provided for a method for manufacturing a semiconductor light emitting device with reference to FIGS. 18 to 19. FIGS. 18 to 19 are cross-sectional views showing the respective steps for manufacturing the light emitting device.

As shown in FIG. 18, the groove 52 is formed in the active region 80b, which includes the n-side transparent electrode 3, the n-type contact layer 4, the MQW light emitting layer 5, the p-type contact layer 6 and the p-side transparent electrode 7 which are formed and stacked on a support member 53, by RIE (reactive ion etching) using a mask material (not illustrated) as a mask, for example.

Next, as shown in FIG. 19, after the mask material is removed, an insulator is formed in the groove 52 to cover the groove 52 and on the p-side transparent electrode 7. The isolation region 51 is formed by subjecting the insulator to planarization polishing by CMP (chemical mechanical polishing), for example. Because the ensuing steps are the same as those of the first embodiment, descriptions for such steps will be omitted.

The semiconductor light emitting device 92 emits light, which is produced in the MQW light emitting layer 5, through the n-side transparent electrode 3 made of the ITO film and placed on the lower side, and through the p-side transparent electrode 7 made of the ITO film and placed on the upper side, as well as through the transparent conductive film 9 made of the ITO film and placed on the upper and lateral sides. In addition, because no anode electrode is formed on the upper surface of the active region 80b, the light extraction efficiency can be enhanced to a large extent.

Furthermore, the semiconductor light emitting device 92 makes it possible to reduce the chip size of the relatively expensive nitride-based semiconductor light emitting device, because the anode electrode 10 and the cathode electrode 11, which are the non-active regions, are formed on the substrate 1/the electrically-conductive reflection film 2, because the inexpensive substrate is used as the substrate 1, and because only the active region 80b is formed from the GaN-based semiconductor layer.

As described above, in the semiconductor light emitting device and the method for manufacturing the same of the embodiment, the cathode electrode 11 and the active region 80b are provided on the substrate 1/the electrically-conductive reflection film 2, and the anode electrode 10 is provided on the transparent conductive film 9. The transparent conductive film 9 is provided on the upper surface of the active region 80b. The transparent conductive film 9 connects the p-side transparent electrode, which is provided to the active region 80b, and the anode electrode 10 together. The active region 80b includes the n-side transparent electrode 3, the n-type contact layer 4, the MQW light emitting layer 5, the p-type contact layer 6 and the p-side transparent electrode 7 which are formed and stacked. The active region 80b also includes an isolation region 51 provided to a lateral surface of the active region 80b. The light produced in the MQW light emitting layer 5 is emitted through the n-side transparent electrode 3 made of the ITO film and placed on the lower side, and through the p-side transparent electrode 7 made of the ITO film and placed on the upper side, as well as through the transparent conductive film 9 made of the ITO film and placed on the upper and lateral sides.

Accordingly, because no anode electrode is formed on the upper surface of the active region 80b, the light extraction efficiency can be enhanced to a large extent. Moreover, it is possible to reduce the chip size of the active region 80b which operates as the light emitting element, and to decrease the costs of the semiconductor light emitting device 92 to a large extent, because the anode electrode 10 and the cathode electrode 11, which are the non-active regions, are formed on the substrate 1/the electrically-conductive reflection film 2, because the inexpensive silicon substrate is used as the substrate 1, and because only the active region 80b is made of the GaN-based semiconductor layer.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light emitting device, comprising:
an electrically-conductive reflection film provided on a substrate;
an active region including a first transparent electrode, a first conductivity type contact layer, a light emitting layer, a second conductivity type contact layer and a second transparent electrode which are formed and stacked on the electrically-conductive reflection film;
a first electrode provided away from the active region on the electrically-conductive reflection film;
an insulating film provided to a lateral surface of the active region, the insulating film being provided away from the active region on the electrically-conductive reflection film;
a transparent conductive film provided to have one end covering an upper portion of the second conductivity type transparent electrode, the transparent conductive film being provided to have the other end placed on the electrically-conductive reflection film through an insulating film, the transparent conductive film being provided to be in contact with a lateral surface of the active region through the insulating film; and
a second electrode provided on the other end of the transparent conductive film.

2. The semiconductor light emitting device according to claim 1, wherein the first transparent electrode, the second transparent electrode and the transparent conductive film are each made of any of an ITO film, a ZnO film, an AZO film and a GZO film.

3. The semiconductor light emitting device according to claim 1, further comprising:
a first conductivity type clad layer provided between the first conductivity type contact layer and the light emitting layer; and
a second conductivity type clad layer provided between the light emitting layer and the second conductivity type contact layer.

4. The semiconductor light emitting device according to claim 1, wherein the active region has a cross section of a trapezoid shape whose lower side is longer than an upper side.

5. The semiconductor light emitting device according to claim 1, wherein the light emitting layer has any one of a MQW structure in which barrier layers and well layers are alternately provided, and a SQW structure in which a well layer is provided between barrier layers.

6. The semiconductor light emitting device according to claim 1, wherein the electrically-conductive reflection film is made of any one of a Ag (silver)-Pd (palladium)-Cu (copper)-Ge (germanium)-based silver alloy, a Ag (silver)-Ge (germanium)-based silver alloy and a Ag (silver)-Au (gold)-Sn (tin)-based silver alloy.

7. A semiconductor light emitting device, comprising:
an electrically-conductive reflection film provided on a substrate;
an active region including a first transparent electrode, a first conductivity type contact layer, a light emitting layer and a second conductivity type contact layer which are formed and stacked on the electrically-conductive reflection film;
a first electrode provided away from the active region on the electrically-conductive reflection film;
an isolation region provided to an end portion of the active region;
an insulating film provided away from the active region on the electrically-conductive reflection film;
a second transparent electrode provided to have one end covering an upper portion of the second conductivity type contact layer, the second transparent electrode being provided to have the other end placed on the electrically-conductive reflection film through an insulating film, the second transparent electrode being provided to be in contact with a lateral surface of the active region through the insulating film; and
a second electrode provided on the other end of the second transparent electrode.

8. The semiconductor light emitting device according to claim 7, wherein the first transparent electrode, the second transparent electrode and the transparent conductive film are each made of any of an ITO film, a ZnO film, an AZO film and a GZO film.

9. The semiconductor light emitting device according to claim 7, further comprising:
a first conductivity type clad layer provided between the first conductivity type contact layer and the light emitting layer; and
a second conductivity type clad layer provided between the light emitting layer and the second conductivity type contact layer.

10. The semiconductor light emitting device according to claim 7, wherein the active region has a cross section of a trapezoid shape whose lower side is longer than an upper side.

11. The semiconductor light emitting device according to claim 7, wherein the light emitting layer has any one of a MQW structure in which barrier layers and well layers are alternately provided and a SQW structure in which a well layer is provided between barrier layers.

12. The semiconductor light emitting device according to claim 7, wherein the electrically-conductive reflection film is made of any one of a Ag (silver)-Pd (palladium)-Cu (copper)-Ge (germanium)-based silver alloy, a Ag (silver)-Ge (germanium)-based silver alloy and a Ag (silver)-Au (gold)-Sn (tin)-based silver alloy.

13. A method for manufacturing a semiconductor light emitting device, comprising:
forming and stacking an n-type contact layer, a MQW light emitting layer and a p-type contact layer on a first substrate by epitaxial growth;
forming and stacking a p-side transparent electrode and an adhesive sheet on the p-type contact layer;
detaching the first substrate by forming a detachment interface between the first substrate and the n-type contact layer by irradiating the first substrate with a laser beam from a back side of the first substrate to an n-type contact layer side;
forming an n-side transparent electrode on the n-type contact layer;
dividing an active region into chips, the active region including the n-side transparent electrode, the n-type contact layer, the MQW light emitting layer, the p-type contact layer and the p-side transparent electrode which are formed and stacked;
forming an electrically-conductive reflection film on a second substrate;
placing a chip having the active region on the electrically-conductive reflection film, and bonding the chip having the active region to the electrically-conductive reflection film and the second substrate;
forming an insulating film on the electrically-conductive reflection film and on a lateral surface of the chip having the active region;
forming a transparent conductive film covering an upper portion of the p-side transparent electrode as well as a lateral surface and an upper portion of the insulating film, the transparent conductive film isolated from the n-side transparent electrode, the n-type contact layer, the MQW light emitting layer and the p-side contact layer by the insulating film; and
forming a cathode electrode on an exposed portion of the electrically-conductive reflection film, and an anode electrode on the transparent conductive film in a region where the second substrate, the electrically-conductive reflection film, the insulating film and the transparent conductive film are formed and stacked.

14. The method according to claim 13, wherein
the first substrate is a sapphire substrate, and
the second substrate is a silicon substrate.

15. The method according to claim 13, wherein
the first substrate is a silicon substrate.

16. The method according to claim 13, wherein
the p-side transparent electrode, the n-side transparent electrode and the transparent conducive film are each made of any of an ITO film, a ZnO film, an AZO film and a GZO film.

17. The method according to claim 13, wherein
the p-side transparent electrode, the n-side transparent electrode and the transparent conducive film are formed by any one of sputtering and evaporation.

18. The method according to claim 13, wherein
the active region is divided into pieces by scribing and breaking or by blade dicing.
